(19) United States
(12) Patent Application Publication
(10) Pub. No.: US 2020/0369935 A1
(43) Pub. Date: Nov. 26, 2020

(54) HEAT-RADIATING SUBSTRATE

(71) Applicant: LG INNOTEK CO., LTD., Seoul (KR)

(72) Inventors: Se Woong NA, Seoul (KR); Jae Man PARK, Seoul (KR)

(21) Appl. No.: 16/959,740

(22) PCT Filed: Dec. 19, 2018
(86) PCT No.: PCT/KR2018/016239

§ 371 Date: Jul. 2, 2020

(30) Foreign Application Priority Data
Jan. 4, 2018 (KR) 10-2018-0001210

(51) Int. Cl. C09K 5/14; C09J 163/00; C09J 11/04; H01L 33/64; B32B 7/12; B32B 15/01; B32B 15/20

(52) U.S. Cl. CPC C09K 5/14; C09J 163/00; C09J 11/04; H01L 33/647; H05K 1/0373; B32B 7/12; B32B 15/01; B32B 15/20; H01L 33/641

(57) ABSTRACT

A heat-radiating substrate according to an embodiment of the present invention comprises: a first metal layer; an insulating layer disposed on the first metal layer and including an epoxy resin and an inorganic filler; and a second metal layer disposed on the insulating layer, wherein the insulating layer comprises: a first region comprising a first surface in contact with the first metal layer; and a second region comprising a second surface in contact with the second metal layer, wherein the inorganic filler comprises a boron nitride aggregate and aluminum oxide, wherein the weight ratio of the aluminum oxide to the total weight of the inorganic filler on the first face is 0.95 to 1.05 times the weight ratio of the aluminum oxide to the total weight of the inorganic filler on the second face.

### TECHNICAL FIELD

The present invention relates to a heat-radiating substrate.

### BACKGROUND ART

Light-emitting devices including a light-emitting element such as a light-emitting diode (LED) or the like are used as various types of light sources. As semiconductor techniques develop, high outputs of light-emitting elements are accelerating. In order to stably cope with large amounts of light and heat emitted from the light-emitting elements, heat radiation performance in the light-emitting elements is in demand.

Further, with the high integration and high capacity of electronic components, there is a growing interest in the heat radiation problem of a printed circuit board on which the electronic components are mounted. In addition, interest in heat radiation problems in semiconductor devices, ceramic substrates, and the like is also increasing.

In general, a resin composition including a resin and an inorganic filler may be used for heat radiation in a light-emitting element, a printed circuit board, a semiconductor device, and a ceramic substrate.

FIG. 1 is an example of a heat-radiating substrate, and FIG. 2 illustrates a method of manufacturing the heat-radiating substrate of FIG. 1.

Referring to FIG. 1, a heat-radiating substrate 1 may include a first metal layer 10, an insulating layer 20 disposed on the first metal layer 10, and a second metal layer 30 disposed on the insulating layer 20. Here, the insulating layer 20 includes a resin composition including a resin and an inorganic filler, and the inorganic filler may include aluminum oxide and boron nitride in order to obtain high heat radiation performance.

Referring to FIG. 2, in order to manufacture the heat-radiating substrate 1, the first metal layer 10 may be coated with the resin composition and dried (FIG. 2A), and the second metal layer 30 may be disposed on the resin composition and then pressurized (FIG. 2B). At this time, the inorganic filler may precipitate downward during the coating and drying process of the resin composition. In particular, when the resin composition includes heterogeneous inorganic fillers having different densities, the inorganic filler having a high density may have a greater tendency to precipitate downward farther than the inorganic filler having a low density. FIG. 3 is a set of optical microscope pictures of an upper surface (a) in contact with the second metal layer 30 and a lower surface (b) in contact with the first metal layer 10 after coating the first metal layer 10 with a resin composition including aluminum oxide and boron nitride as an inorganic filler and drying. Referring to FIG. 3, it can be seen that the distribution of the inorganic fillers is different in the upper surface (a) and the lower surface (b). That is, the density of aluminum oxide is about 3.8 g/cm3, and the density of boron nitride aggregate is about 2.2 g/cm3, and thus the density of the aluminum oxide is greater than that of the boron nitride aggregate. Accordingly, in the heat-radiating substrate 1 manufactured according to the method of FIG. 2, the aluminum oxide may be more distributed in the lower surface of the insulating layer 20 in contact with the first metal layer 10 than the upper surface of the insulating layer 20 in contact with the second metal layer 30, and the boron nitride aggregate may be more distributed in the upper surface of the insulating layer 20 in contact with the second metal layer 30 than the lower surface of the insulating layer 20 in contact with the first metal layer 10. The higher the content of aluminum oxide, the better the bonding force between a metal layer and an insulating layer, but the higher the content of boron nitride aggregate, the worse the bonding force between a metal layer and an insulating layer so that the bonding strength between the insulating layer 20 and the first metal layer 10 may be different from the bonding strength between the insulating layer 20 and the second metal layer 30. The difference between the bonding strength between the insulating layer 20 and the first metal layer 10 and the bonding strength between the insulating layer 20 and the second metal layer 30 may adversely affect the performance of a heat-radiating substrate.

### DISCLOSURE

### Technical Problem

The present invention is directed to providing a substrate having excellent heat radiation performance and bonding strength.

### Technical Solution

One aspect of the present invention provides a heat-radiating substrate including a first metal layer, an insulating layer disposed on the first metal layer and including an epoxy resin and an inorganic filler containing a boron nitride aggregate and aluminum oxide, and a second metal layer disposed on the insulating layer, wherein the insulating layer may include a first region including a first surface in contact with the first metal layer and a second region including a second surface in contact with the second metal layer, and a ratio of a weight of the aluminum oxide to a total weight of the inorganic filler in the first surface may be 0.95 to 1.05 times a ratio of a weight of the aluminum oxide to a total weight of the inorganic filler in the second surface.

The insulating layer may further include a third region disposed between the first region and the second region, heights of the first region, the second region, and the third region may be the same, the ratio of the weight of the aluminum oxide to the total weight of the inorganic filler in the first surface may be greater than a ratio of a weight of the aluminum oxide to a total weight of the inorganic filler in the third region, and the ratio of the weight of the aluminum oxide to the total weight of the inorganic filler in the second surface may be greater than the ratio of the weight of the aluminum oxide to the total weight of the inorganic filler in the third region.

The ratio of the weight of the aluminum oxide to the total weight of the inorganic filler in the first surface may exceed 1.05 times the ratio of the weight of the aluminum oxide to the total weight of the inorganic filler in the third region, and the ratio of the weight of the aluminum oxide to the total weight of the inorganic filler in the second surface may exceed 1.05 times the ratio of the weight of the aluminum oxide to the total weight of the inorganic filler in the third region.

A bonding strength between the first metal layer and the first surface may be 0.8 to 1.2 times a bonding strength between the second metal layer and the second surface.

The bonding strength between the first metal layer and the first surface and the bonding strength between the second metal layer and the second surface may all be 0.7 kgf/cm or more.

The aluminum oxide may be included in an amount of 50 wt % to 80 wt % with respect to the total weight of the inorganic filler in the first surface.

The inorganic filler may further include aluminum nitride.

Another aspect of the present invention provides a heat-radiating substrate including a first metal layer, an insulating layer disposed on the first metal layer and including an epoxy resin and an inorganic filler containing a boron nitride aggregate and aluminum oxide, and a second metal layer disposed on the insulating layer, wherein the insulating layer may include a first region including a first surface in contact with the first metal layer and a second region including a second surface in contact with the second metal layer, and a particle size D50 of the inorganic filler in the first surface may be 0.95 to 1.05 times a particle size D50 of the inorganic filler in the second surface.

### Advantageous Effects

According to an embodiment of the present invention, a substrate having excellent heat radiation performance can be achieved. In addition, the substrate according to the embodiment of the present invention can have a high bonding strength between an insulating layer and a metal layer and is easy to mount components thereon. In particular, according to the embodiment of the present invention, a similar level of bonding strength can be achieved on both sides of the insulating layer.

### DESCRIPTION OF DRAWINGS

FIG. 1 is an example of a heat-radiating substrate, and FIG. 2 illustrates a method of manufacturing the heat-radiating substrate of FIG. 1.

FIG. 3 is a set of optical microscope pictures of an upper surface (a) in contact with a second metal layer and a lower surface (b) in contact with a first metal layer after coating the first metal layer with a resin composition including aluminum oxide and boron nitride as an inorganic filler and drying.

FIG. 4 is a cross-sectional view of a heat-radiating substrate according to one embodiment of the present invention.

FIG. 5 illustrates a method of manufacturing the heat-radiating substrate according to one embodiment of the present invention.

FIG. 6 is data for illustrating changes in bonding strength according to the type and content of an inorganic filler.

FIG. 7 is an example of a metal layer applied to the heat-radiating substrate according to one embodiment of the present invention.

FIG. 8 is a cross-sectional view of a light-emitting element module according to one embodiment of the present invention.

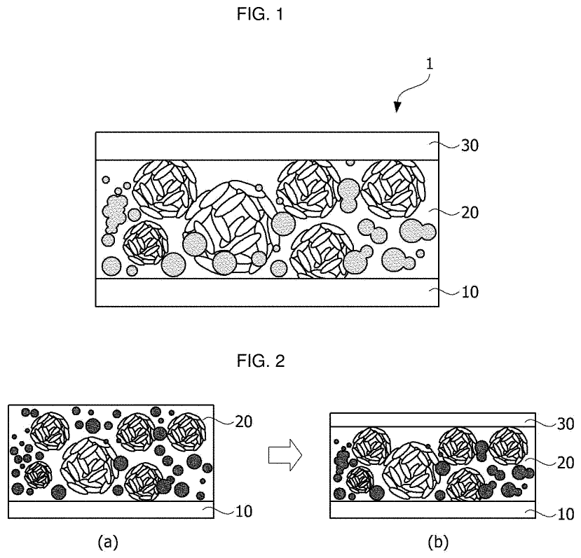

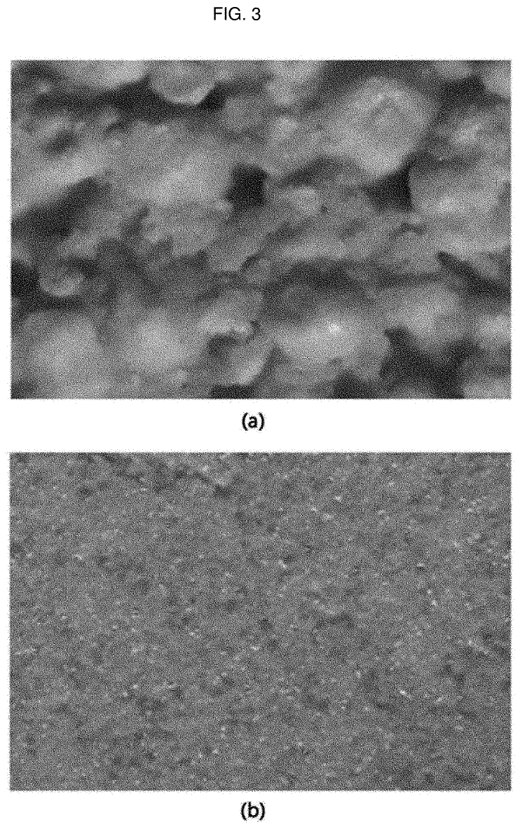

### MODES OF THE INVENTION

The present invention may be variously modified and may be implemented in various forms, and specific embodiments will be exemplified in the drawings and described. However, the present invention is not intended to be limited to the specific embodiments, and it should be understood that the present invention covers all such modifications, equivalents, and substitutes within the spirit and the technical scope of the present invention.

It will be understood that, although the terms “first,” “second,” or the like may be used herein to describe various elements, these elements should not be limited by these terms. These terms are only used to distinguish one element from another. For example, a first element could be termed a second element, and similarly, a second element could be termed a first element without departing from the scope of the present invention. As used herein, the term “and/or” includes any combination or one of a plurality of associated listed items.

The terms used herein are for the purpose of describing particular embodiments only and is not intended to be limiting of the present invention. As used herein, the singular forms are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined here.

When it is stated that a part of a layer, film, area, plate, and the like is “on” another part, the statement includes the meaning of the part “being directly on” the other part in addition to still another part being interposed therebetween. On the other hand, when it is stated that a part is “directly on” another part, no other part exists therebetween.

Hereinafter, embodiments will be described in detail with reference to the accompanying drawings, like reference numerals designate like elements throughout the specification, and the repeated description thereof will be omitted.

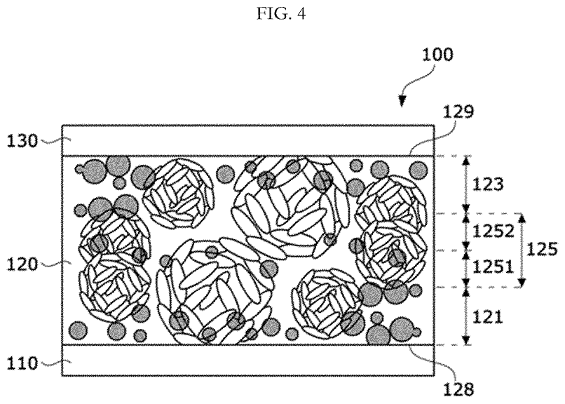

FIG. 4 is a cross-sectional view of a heat-radiating substrate according to one embodiment of the present invention.

Referring to FIG. 4, a heat-radiating substrate 100 according to the embodiment of the present invention includes a first metal layer 110, an insulating layer 120 disposed on the first metal layer 110, and a second metal layer 130 disposed on the insulating layer 120. Here, the first metal layer 110 and the second metal layer 130 may include copper (Cu) or nickel (Ni) and may be circuit patterns.

The insulating layer 120 may include a resin composition including a resin and an inorganic filler.

Here, the resin may include an epoxy compound and a curing agent. Here, the curing agent may be included in a volume ratio of 1 to 10 with respect to 10 volume ratios of the epoxy compound. In the present specification, the epoxy compound may be used interchangeably with an epoxy-based resin. Here, the epoxy compound may include at least one of a crystalline epoxy compound, a non-crystalline epoxy compound, and a silicone epoxy compound. The crystalline epoxy compound may include a mesogen structure. The mesogen is a basic unit of a liquid crystal and includes a rigid structure. In addition, the non-crystalline epoxy compound may be a normal non-crystalline epoxy compound having two or more epoxy groups in its molecules and, for example, may be a glycidyl ether compound derived from bisphenol A or bisphenol F. Here, the curing agent may include at least one from among an amine-based curing agent, a phenol-based curing agent, an acid anhydride-based curing agent, a polymercaptan-based curing agent, a polyaminoamide-based curing agent, an isocyanate-based curing agent, and a block isocyanate-based curing agent, and two or more kinds of these curing agents may be mixed and used as the curing agent.

The inorganic filler may include aluminum oxide and boron nitride. Here, the boron nitride may include a boron nitride aggregate in which a plurality of plate-shaped boron nitrides are agglomerated. The inorganic filler may further include aluminum nitride.

Here, the aluminum oxide may have a particle diameter of 0.2 to 120 μm, preferably 1 to 100 μm, and more preferably 2 to 90 μm, and the boron nitride aggregate may have a particle diameter of 40 to 500 μm, preferably 100 to 400 μm, and more preferably 200 to 300 μm. Here, the surface of the boron nitride aggregate may be coated with a polymer having Unit 1 below, or at least some pores in the boron nitride aggregate may be filled with the polymer having Unit 1 below.

Unit 1 is as follows,

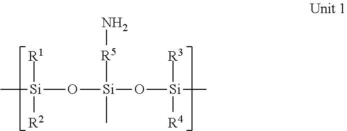

where one of R1, R2, R3, and R4 may be H, the remainder may be selected from the group consisting of an alkyl group having 1 to 3 carbon atoms, an alkene group having 2 to 3 carbon atoms, and an alkyne group having 2 to 3 carbon atoms, and R5 may be a linear, branched, or cyclic divalent organic linker having 1 to 12 carbon atoms.

In one embodiment, one of R1, R2, R3, and R4, excluding H, may be selected from an alkene group having 2 to 3 carbon atoms, and another one and the other one of the remainders may be selected from an alkyl group having 1 to 3 carbon atoms. For example, the polymer according to the embodiment of the present invention may include Unit 2 below.

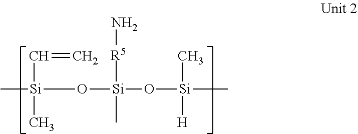

Alternatively, the remainder of R1, R2, R3, and R4, excluding H, may be selected to be different from each other in the group consisting of an alkyl group having 1 to 3 carbon atoms, an alkene group having 2 to 3 carbon atoms, and an alkyne group having 2 to 3 carbon atoms.

As described above, when the boron nitride aggregate, in which plate-shaped boron nitrides are agglomerated, is coated with the polymer according to Unit 1 or Unit 2 and the polymer is filled in at least some pores in the boron nitride aggregate, an air layer in the boron nitride aggregate may be minimized, and thus thermal conductivity of the boron nitride aggregate may be increased, and the bonding strength between the plate-shaped boron nitrides may be increased, and thereby the boron nitride aggregate may be prevented from breaking. In addition, when a coating layer is formed on the boron nitride aggregate, in which plate-shaped boron nitrides are agglomerated, a functional group may be easily formed, and when the functional group is formed on the coating layer of the boron nitride aggregate, chemical affinity between the boron nitride aggregate and the resin may be increased.

Meanwhile, according to the embodiment of the present invention, the insulating layer 120 may include a first region 121 including a first surface 128 in contact with the first metal layer 110, a second region 123 including a second surface 129 in contact with the second metal layer 130, and a third region 125 disposed between the first region 121 and the second region 123. Heights of the first region 121, the second region 123, and the third region 125 may all be the same. In addition, the third region 125 may include a fourth region 127 disposed at a side of the first region 121 and a fifth region 129 disposed at a side of the second region 123, and heights of the fourth region 127 and the fifth region 129 may be the same. The first region 121, the second region 123, the third region 125, the fourth region 127, and the fifth region 129 are only regions that are arbitrarily divided in order to explain the embodiment of the present invention and are not regions visually distinguished by a layer.

According to the embodiment of the present invention, the distribution of the inorganic filler in the first surface 128 may be similar to the distribution of the inorganic filler in the second surface 129.

That is, a ratio WB1/WT1 of a weight WB1 of the aluminum oxide to a total weight WT1 of the inorganic filler in the first surface 128 may be similar to a ratio WB2/WT2 of a weight WB2 of the aluminum oxide to a total weight WT2 of the inorganic filler in the second surface 129. For example, the ratio WB1/WT1 of the weight WB1 of the aluminum oxide to the total weight WT1 of the inorganic filler in the first surface 128 may be 0.95 to 1.05 times, preferably 0.97 to 1.03 times, and more preferably 0.99 to 1.01 times the ratio WB2/WT2 of the weight WB2 of the aluminum oxide to the total weight WT2 of the inorganic filler in the second surface 129. For example, the aluminum oxide may be included in an amount of 50 to 80 wt % with respect to the total weight WT1 of the inorganic filler in the first surface 128, and the aluminum oxide may be included in an amount of 50 to 80 wt % with respect to the total weight WT2 of the inorganic filler in the second surface 129.

According to another embodiment of the present invention, the distribution of the inorganic filler in the first region 121 may be similar to the distribution of the inorganic filler in the second region 123.

That is, a ratio WB11/WT11 of a weight WB11 of the aluminum oxide to a total weight WT11 of the inorganic filler in the first region 121 may be similar to a ratio WB22/WT22 of a weight WB22 of the aluminum oxide to a total weight WT22 of the inorganic filler in the second region 123. For example, the ratio WB11/WT11 of the weight WB11 of aluminum oxide to the total weight WT11 of the inorganic filler in the first region 121 may be 0.95 to 1.05 times, preferably 0.97 to 1.03 times, and more preferably 0.99 to 1.01 times the ratio WB22/WT22 of the weight WB22 of the aluminum oxide to the total weight WT22 of the inorganic filler in the second region 123.

Accordingly, a particle size D50 of the inorganic filler in the first region 121 may be similar to a particle size D50 of the inorganic filler in the second region 123. D50 refers to a particle diameter corresponding to 50 percent by weight in the particle size distribution curve, that is, a particle diameter in which the passing mass percentage is 50%, and may be referred to as an average particle diameter. For example, the particle size D50 of the inorganic filler in the first region 121 may be 0.95 to 1.05 times, preferably 0.97 to 1.03 times, and more preferably 0.99 to 1.01 times the particle size D50 of the inorganic filler in the second region 123.

Depending on the type of the inorganic filler, the surface properties may be different, and accordingly, the wettability with the resin in which the inorganic filler is dispersed may be different, and the bonding force between an insulating layer, including the inorganic filler, and a metal layer may be different. For example, the aluminum oxide has a surface less smooth than that of the boron nitride aggregate, has good wettability with an epoxy resin, and thus may increase the bonding force with a metal layer.

When the distribution of the inorganic filler in the first region 121 is similar to the distribution of the inorganic filler in the second region 123 as in the embodiment of the present invention, the bonding strength between the first metal layer 110 and the insulating layer 120 may be similar to the bonding strength between the second metal layer 130 and the insulating layer 120. That is, the bonding strength between the first metal layer 110 and the first surface 128 may be similar to the bonding strength between the second metal layer 130 and the second surface 129.

Meanwhile, according to the embodiment of the present invention, the ratio WB11/WT11 of the weight WB11 of the aluminum oxide to the total weight WT11 of the inorganic filler in the first region 121 may be greater than a ratio WB3/WT3 of a weight WB3 of the aluminum oxide to a total weight WT3 of the inorganic filler in the third region 125, and the ratio WB22/WT22 of the weight WB22 of the aluminum oxide to the total weight WT22 of the inorganic filler in the second region 123 is greater than the ratio WB3/WT3 of the weight WB3 of the aluminum oxide to the total weight WT3 of the inorganic filler in the third region 125. For example, the ratio WB11/WT11 of the weight WB11 of the aluminum oxide to the total weight WT11 of the inorganic filler in the first region 121 may exceed 1.05 times the ratio WB3/WT3 of the weight WB3 of the aluminum oxide to the total weight WT3 of the inorganic filler in the third region 125, and the ratio WB22/WT22 of the weight WB22 of the aluminum oxide to the total weight WT22 of the inorganic filler in the second region 123 may exceed 1.05 times the ratio WB3/WT3 of the weight WB3 of the aluminum oxide to the total weight WT3 of the inorganic filler in the third region 125. However, the ratio WB11/WT11 of the weight WB11 of the aluminum oxide to the total weight WT11 of the inorganic filler in the first region 121 may not exceed 2 times, preferably 1.5 times, and more preferably 1.2 times the ratio WB3/WT3 of the weight WB3 of the aluminum oxide to the total weight WT3 of the inorganic filler in the third region 125, and the ratio WB22/WT22 of the weight WB22 of the aluminum oxide to the total weight WT22 of the inorganic filler in the second region 123 may not exceed 2 times, preferably 1.5 times, and more preferably 1.2 times the ratio WB3/WT3 of the weight WB3 of the aluminum oxide to the total weight WT3 of the inorganic filler in the third region 125. When the ratio WB11/WT11 of the weight WB11 of the aluminum oxide to the total weight WT11 of the inorganic filler in the first region 121 exceeds 2 times the ratio WB3/WT3 of the weight WB3 of the aluminum oxide to the total weight WT3 of the inorganic filler in the third region 125, or the ratio WB2/WT22 of the weight WB22 of the aluminum oxide to the total weight WT22 of the inorganic filler in the second region 123 exceeds 2 times the ratio WB3/WT3 of the weight WB3 of the aluminum oxide to the total weight WT3 of the inorganic filler in the third region 125, heat radiation performance in the insulating layer 120 may be unevenly distributed.

However, even when there is a difference in the content of the inorganic filler between the first region 121 and the third region 125 or between the second region 123 and the third region 125, a ratio WB11+B4/WT11+T4 of a weight W611+B4 of the aluminum oxide to a total weight WT11+T4 of the inorganic fillers in the first region 121 and the fourth region 127 may be similar to a ratio WB22+B5/WT22+T5 of a weight WB22+B5 of the aluminum oxide to a total weight WT22+T5 of the inorganic fillers in the second region 123 and the fifth region 129. For example, the ratio WB11+B4/WT11+T4 of the weight WB11+B4 of the aluminum oxide to the total weight WT11+T4 of the inorganic fillers in the first region 121 and the fourth region 127 may be 0.95 to 1.05 times, preferably 0.97 to 1.03 times, and more preferably 0.99 to 1.01 times the ratio WB22+B5/WT22+T5 of the weight WB22+B5 of the aluminum oxide to the total weight WT22+T5 of the inorganic fillers in the second region 123 and the fifth region 129.

Accordingly, the particle size D50 of the inorganic fillers in the first region 121 and the fourth region 127 may be similar to the particle size D50 of the inorganic fillers in the second region 123 and the fifth region 129. For example, the particle size D50 of the inorganic fillers in the first region 121 and the fourth region 127 may be 0.95 to 1.05 times, preferably 0.97 to 1.03 times, and more preferably 0.99 to 1.01 times the particle size D50 of the inorganic fillers in the second region 123 and the fifth region 129.

As described above, when the inorganic filler content of the first region 121 and the fourth region 127 is similar to that of the second region 123 and the fifth region 129, the bonding strength between the first metal layer 110 and the insulating layer 120 may be similar to the bonding strength between the second metal layer 130 and the insulating layer 120, and also the entire insulating layer 120 may have uniform heat radiation performance.

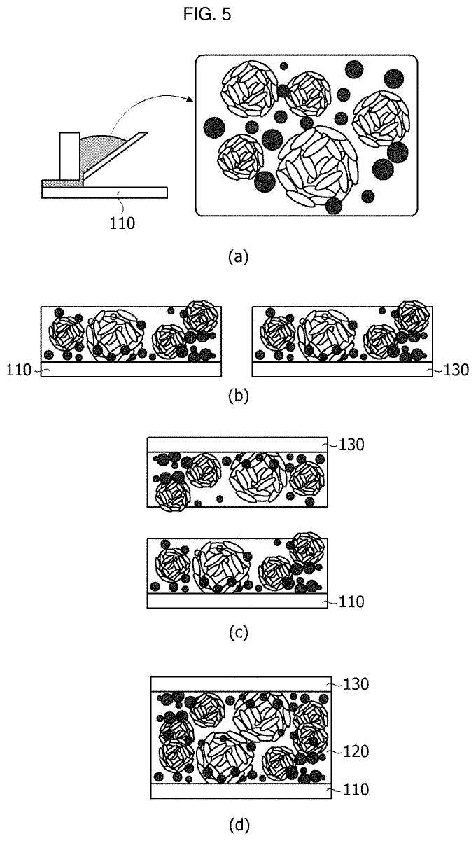

The heat-radiating substrate according to the embodiment of the present invention may be manufactured according to a method illustrated in FIG. 5.

Referring to FIG. 5A, a first metal layer 110 is coated with a resin composition including an epoxy resin, a boron nitride aggregate, and aluminum oxide to a predetermined thickness.

Referring to FIG. 5B, a second metal layer 130 is coated with the resin composition to a predetermined thickness in the same manner as the first metal layer 110 is coated with the resin composition.

Afterward, as shown in FIG. 5C, the resin composition coated on the first metal layer 110 and the resin composition coated on the second metal layer 130 are placed to face each other and then pressurized as shown in FIG. 5D.

According to the manufacturing method, since the aluminum oxide has a higher density than the boron nitride aggregate, the volume ratio or mass ratio of the aluminum oxide to the entire inorganic fillers distributed in the region adjacent to the first metal layer 110 and the region adjacent to the second metal layer 130 may be greater than the volume ratio or mass ratio of the aluminum oxide to the inorganic filler distributed in the middle region between the first metal layer 110 and the second metal layer 130, and the volume ratio or mass ratio of the aluminum oxide to the inorganic filler distributed in the region adjacent the first metal layer 110 may be similar to the volume ratio or mass ratio of the aluminum oxide to the inorganic filler distributed in the region adjacent the second metal layer 130.

The greater the content of the aluminum oxide, the higher the bonding strength between the insulating layer and the metal layer, and thus the space between the first metal layer 110 and an insulating layer 120 and the space between the second metal layer 130 and the insulating layer 120 may have a high bonding strength at a similar level.

Hereinafter, the embodiment of the present invention will be described in detail with reference to Comparative Examples and Examples.

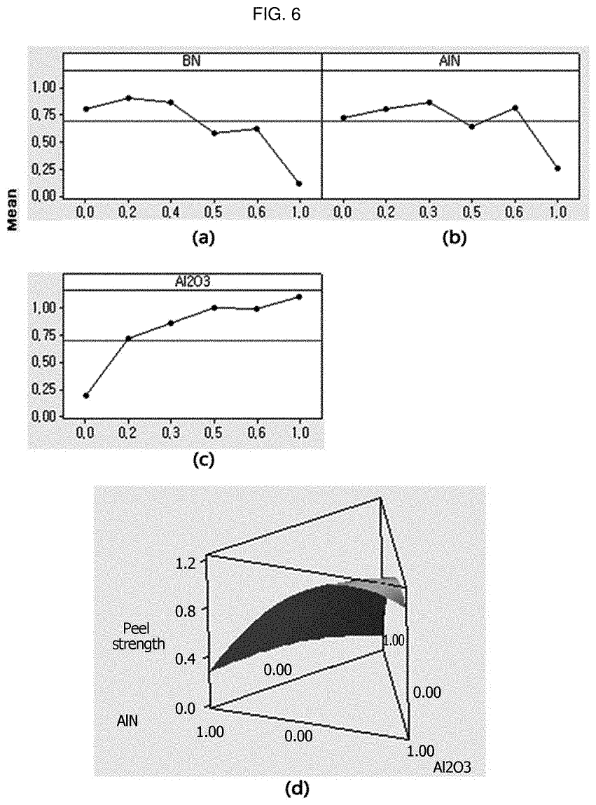

First, Table 1 and FIG. 6 are data for illustrating changes in the bonding strength according to the type and content of the inorganic filler.

TABLE 1

| NO. | BN | AlN | Al₂O₃ |
|---|---|---|---|
| 1 | 1 | 0 | 0 |
| 2 | 0 | 1 | 0 |
| 3 | 0 | 0 | 1 |
| 4 | 0.5 | 0.5 | 0 |
| 5 | 0.5 | 0 | 0.5 |
| 6 | 0 | 0.5 | 0.5 |
| 7 | 0.4 | 0.3 | 0.3 |
| 8 | 0.6 | 0.2 | 0.2 |
| 9 | 0.2 | 0.6 | 0.2 |
| 10 | 0.2 | 0.2 | 0.6 |

The results of FIG. 6 were obtained as a result of performing the design of experiment (DOE) after adjusting BN, AlN, and Al2O3 as the content ratio in Table 1. In Table 1, experiments were designed with relative volumes when the total volume of each of BN, AlN, and Al2O3 was set to 1.

In FIGS. 6A, 6B, and 6C, the horizontal axis of the graph represents the content of each of BN, AlN, and Al2O3, and the vertical axis thereof represents the bonding strength with the metal layer. Referring to FIG. 6A, it can be seen that the greater the content of BN, the lower the bonding strength. In addition, referring to FIG. 6C, the greater the content of Al2O3, the greater the bonding strength.

Next, according to Example, a heat-radiating substrate was manufactured in a manner that a first copper layer was coated with a resin composition including an epoxy resin, a boron nitride aggregate, and aluminum oxide, a second copper layer was coated with a resin composition including an epoxy resin, a boron nitride aggregate, and aluminum oxide, and the resin composition on the first copper layer and the resin composition on the second copper layer are placed and pressurized to face each other. In addition, according to Comparative Example, a heat-radiating substrate was manufactured in a manner that a first copper layer was coated with a resin composition including an epoxy resin, a boron nitride aggregate, and aluminum oxide, and then a second copper layer was placed on the resin composition and pressurized. At this point, the heat-radiating substrate was manufactured such that the sum of the thickness of the resin composition coated on each of the first copper layer and the second copper layer in Example was the same as the thickness of the resin composition coated on the first copper layer in Comparative Example.

### Example 1

A first copper layer of 35 μm was coated with a resin composition including 78 vol % of a boron nitride aggregate and aluminum oxide and 22 vol % of a resin containing an epoxy compound, a second copper layer of 35 μm was coated with a resin composition including 78 vol % of a boron nitride aggregate and aluminum oxide and 22 vol % of a resin containing an epoxy compound, and the resultant was pressurized such that the final thickness of an insulating layer was 500 μm.

### Example 2

A first copper layer of 70 μm was coated with a resin composition including 78 vol % of a boron nitride aggregate and aluminum oxide and 22 vol % of a resin containing the same epoxy compound as the epoxy compound of Example 1, a second copper layer of 70 μm was coated with a resin composition including 78 vol % of a boron nitride aggregate and aluminum oxide and 22 vol % of a resin containing an epoxy compound, and the resultant was pressurized such that the final thickness of an insulating layer was 500 μm.

### Comparative Example 1

A first copper layer of 35 μm was coated with a resin composition including 78 vol % of a boron nitride aggregate and aluminum oxide and 22 vol % of a resin containing the same epoxy compound as the epoxy compound of Example 1, a second copper layer of 35 μm was disposed on the resin composition, and the resultant was pressurized such that the final thickness of an insulating layer was 500 μm.

### Comparative Example 2

A first copper layer of 70 μm was coated with a resin composition including 78 vol % of a boron nitride aggregate and aluminum oxide and 22 vol % of a resin containing the same epoxy compound as the epoxy compound of Example 1, a second copper layer of 70 μm was disposed on the resin composition, and the resultant was pressurized such that the final thickness of an insulating layer was 500 μm.

Table 2 shows the results of measuring the bonding strength between the first copper layer and the insulating layer and the bonding strength between the second copper layer and the insulating layer in each of the heat-radiating substrates according to Examples 1 and 2 and Comparative Examples 1 and 2.

TABLE 2

| | Bonding strength (kgf/cm) | Bonding strength (kgf/cm) |
|---|---|---|
| Experimental | between first copper layer | between second copper layer |
| number | and insulating layer | and insulating layer |
| Example 1 | 0.72 | 0.82 |
| Example 2 | 0.84 | 0.83 |
| Comparative | 0.89 | 0.50 |
| Example 1 | | |
| Comparative | 0.77 | 0.37 |
| Example 2 | | |

Referring to Table 2, it can be seen from Examples 1 and 2 that the bonding strength between the first copper layer and the insulating layer is 0.8 to 1.2 times the bonding strength between the second copper layer and the insulating layer, and is similar thereto. In addition, it can be seen from Examples 1 and 2 that the bonding strength between the first copper layer and the insulating layer and the bonding strength between the second copper layer and the insulating layer are all 0.7 kgf/cm or more.

Meanwhile, the heat-radiating substrate according to the embodiment of the present invention may be manufactured using a metal layer having a plurality of recesses formed in advance.

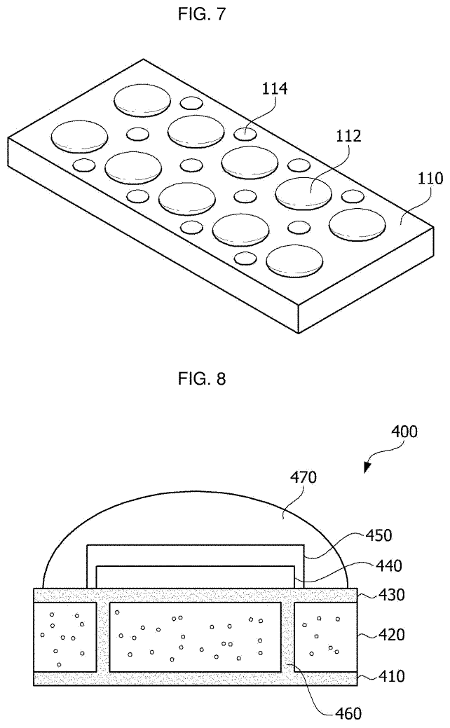

FIG. 7 is an example of the metal layer applied to the heat-radiating substrate according to one embodiment of the present invention.

Referring to FIG. 7, a plurality of first recesses 112 and a plurality of second recesses 114 may be formed in one surface of the metal layer 110 in advance. As previously described, the insulating layer 120 of the heat-radiating substrate 100 according to the embodiment of the present invention is obtained using a resin composition including a resin, a boron nitride aggregate, and aluminum oxide. Here, the boron nitride aggregate may have a particle diameter of 40 to 500 μm, and the aluminum oxide may have a particle diameter of 0.2 to 120 μm, and thus the boron nitride aggregate and the aluminum oxide in the resin composition may protrude through the surface of the resin composition when the metal layer 110 is coated with the resin composition and dried and then pressurized. When the boron nitride aggregate and the aluminum oxide protrude through the surface of the resin composition, the metal layer 110 may be easily torn, and the bonding strength between the metal layer 110 and the insulating layer 120 may be weakened.

As in the embodiment of the present invention, when the plurality of first recesses 112 and the plurality of second recesses 114 are formed in one surface of the metal layer 110 in advance, the boron nitride aggregate and the aluminum oxide, which protrude through the surface of the resin composition, may be accommodated in the plurality of first recesses 112 and the plurality of second recesses 114. Accordingly, the problem in which the metal layer 110 is torn may be minimized, and high thermal conductivity may be achieved due to the increased contact area between the metal layer 110 and the insulating layer 120.

Meanwhile, the heat-radiating substrate according to the embodiment of the present invention may also be applied to a light-emitting element as well as a printed circuit board.

FIG. 8 is a cross-sectional view of a light-emitting element module according to one embodiment of the present invention.

Referring to FIG. 8, a light-emitting element module 400 includes a lower line 410, an insulating layer 420 disposed on the lower line 410, an upper line 430 disposed on the insulating layer 420, a light-emitting element 440 disposed on the upper line 430, a phosphor layer 450 disposed on the light-emitting element 440, a via 460 connecting the lower line 410 to the upper line 430, and a lens 470. Here, the lower line 410, the insulating layer 420, and the upper line 430 may respectively correspond to the first metal layer 110, the insulating layer 120, and the second metal layer 130 according to the embodiment of the present invention, and may form a heat-radiating substrate.

In the above-description, although the present invention has been described with reference to the exemplary embodiments thereof, it will be understood by those of ordinary skill in the art that various modifications and variations are possible without departing from the spirit and scope of the present invention as defined by the following claims.

### DESCRIPTION OF REFERENCE NUMERALS

100: substrate
110: first metal layer
120: insulating layer
130: second metal layer

1. A heat-radiating substrate comprising:
a first metal layer;
an insulating layer disposed on the first metal layer and including an epoxy resin and an inorganic filler; and
a second metal layer disposed on the insulating layer,
wherein the insulating layer includes a first region including a first surface in contact with the first metal layer and a second region including a second surface in contact with the second metal layer,
the inorganic filler includes a boron nitride aggregate and aluminum oxide, and
a ratio of a weight of the aluminum oxide to a total weight of the inorganic filler in the first surface is 0.95 to 1.05 times a weight ratio of a weight of the aluminum oxide to a total weight of the inorganic filler in the second surface.

2. The heat-radiating substrate of claim 1, wherein
the insulating layer further includes a third region disposed between the first region and the second region,
heights of the first region, the second region, and the third region are the same,
the ratio of the weight of the aluminum oxide to the total weight of the inorganic filler in the first surface is greater than a weight ratio of a weight of the aluminum oxide to a total weight of the inorganic filler in the third region, and
the ratio of the weight of the aluminum oxide to the total weight of the inorganic filler in the second surface is greater than the ratio of the weight of the aluminum oxide to the total weight of the inorganic filler in the third region.

3. The heat-radiating substrate of claim 2, wherein
the ratio of the weight of the aluminum oxide to the total weight of the inorganic filler in the first surface exceeds 1.05 times the ratio of the weight of the aluminum oxide to the total weight of the inorganic filler in the third region, and
the ratio of the weight of the aluminum oxide to the total weight of the inorganic filler in the second surface exceeds 1.05 times the ratio of the weight of the aluminum oxide to the total weight of the inorganic filler in the third region.

4. The heat-radiating substrate of claim 1, wherein a bonding strength between the first metal layer and the first surface is 0.8 to 1.2 times a bonding strength between the second metal layer and the second surface.

5. The heat-radiating substrate of claim 4, wherein the bonding strength between the first metal layer and the first surface and the bonding strength between the second metal layer and the second surface are all 0.7 kgf/cm or more.

6. The heat-radiating substrate of claim 1, wherein the aluminum oxide is included in an amount of 50 wt % to 80 wt % with respect to the total weight of the inorganic filler in the first surface.

7. The heat-radiating substrate of claim 1, wherein the inorganic filler further includes aluminum nitride.

8. A heat-radiating substrate comprising:
a first metal layer;
an insulating layer disposed on the first metal layer and including an epoxy resin and an inorganic filler; and
a second metal layer disposed on the insulating layer,
wherein
the insulating layer includes a first region including a first surface in contact with the first metal layer and a second region including a second surface in contact with the second metal layer, and
a particle size (D50) of the inorganic filler in the first surface is 0.95 to 1.05 times a particle size (D50) of the inorganic filler in the second surface.

9. The heat-radiating substrate of claim 8, wherein
the inorganic filler includes a boron nitride aggregate and aluminum oxide,
the insulating layer further includes a third region disposed between the first region and the second region,
heights of the first region, the second region, and the third region are the same,
a ratio of a weight of the aluminum oxide to a total weight of the inorganic filler in the first surface is greater than a weight ratio of a weight of the aluminum oxide to a total weight of the inorganic filler in the third region, and
a ratio of a weight of the aluminum oxide to a total weight of the inorganic filler in the second surface is greater than the ratio of the weight of the aluminum oxide to the total weight of the inorganic filler in the third region.

10. The heat-radiating substrate of claim 8, wherein a bonding strength between the first metal layer and the first surface is 0.8 to 1.2 times a bonding strength between the second metal layer and the second surface.

11. The heat-radiating substrate of claim 3, wherein
the ratio of the weight of the aluminum oxide to the total weight of the inorganic filler in the first surface is less than 2 times the ratio of the weight of the aluminum oxide to the total weight of the inorganic filler in the third region, and
the ratio of the weight of the aluminum oxide to the total weight of the inorganic filler in the second surface is less than 2 times the ratio of the weight of the aluminum oxide to the total weight of the inorganic filler in the third region.

12. The heat-radiating substrate of claim 3, wherein
the third region includes a fourth region disposed at a side of the first region and a fifth region disposed at a side of the second region,
heights of the fourth region and the fifth region are the same, and
the ratio of the weight of the aluminum oxide to the total weight of the inorganic fillers in the first region and the fourth region is 0.95 to 1.05 times the ratio of the weight of the aluminum oxide to the total weight of the inorganic fillers in the second region and the fifth region.

13. The heat-radiating substrate of claim 1, wherein at least one of the first metal layer and the second metal layer includes at least one of copper (Cu) and nickel (Ni).

14. The heat-radiating substrate of claim 1, wherein the boron nitride aggregate has a particle diameter of 40 to 500 μm, and the aluminum oxide has a particle diameter of 0.2 to 120 μm.

15. The heat-radiating substrate of claim 1, wherein a plurality of first recesses and a plurality of second recesses are formed at least one of the first metal layer and the second metal layer, and
the boron nitride aggregate and the aluminum oxide are accommodated in the plurality of first recesses and the plurality of second recesses.
